(19) United States
(12) Patent Application Publication
(10) Pub. No.: US 2006/0182878 A1
(43) Pub. Date: Aug. 17, 2006

(54) Method of producing electronic device

(75) Inventors: Itaru Takaya, Tokyo (JP); Toshihide Kimura, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 11/341,664

(22) Filed: Jan. 30, 2006

(30) Foreign Application Priority Data
Feb. 14, 2005 (JP) 2005-035382

(51) Int. Cl. C23C 28/00; B05D 3/02; B05D 1/36

(52) U.S. Cl. 427/96.8; 427/314; 427/402; 427/374.1; 427/64

(57) ABSTRACT

To provide a method of producing an electronic device which can improve the durability of the device without reducing the initial performance of the device. The method of the present invention is a method of producing an electronic device including: a first organic layer formation step of forming a first organic layer on a first electrode, and a second organic layer formation step of forming a second organic layer on the first organic layer, wherein the method further includes a heating step of heating the first electrode before the first organic layer formation step, and wherein the first organic layer formation step includes a first organic layer vapor-deposition step of forming the first organic layer on the heated first electrode by vapor-deposition and a cooling step of cooling the first organic layer.

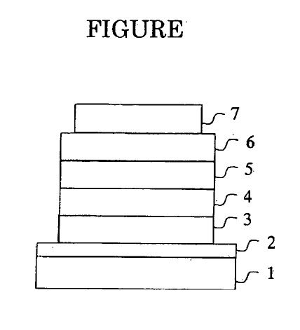

### BACKGROUND OF THE INVENTION

1. Field of the Invention

The present invention relates to a method of producing an electronic device such as an organic light-emitting device.

2. Related Background Art

An electronic device having an organic layer, such as an organic light-emitting device, an organic TFT, or an organic battery, that has been recently attracting attention has various problems resulting from the instability of an organic compound constituting the organic layer.

For example, an organic light-emitting device having a plurality of organic layers sandwiched between a pair of electrodes is known to undergo the deterioration of the organic layers due to heat, water, or the like. Therefore, the organic light-emitting device is requested to have durability such that the device can stably emit light for a long time period. As means for solving such problem, there have been proposed a method of performing a heat treatment at a temperature equal to or lower than the melting point of an organic compound constituting a light-emitting layer after the formation of the light-emitting layer (Japanese Patent Application Laid-Open No. H05-182764, page 2, lines 7-9) and a method of heating a substrate to a temperature 0.7 to 0.9 time as high as the melting point of an organic material constituting each of organic layers including a light-emitting layer at the time of vacuum vapor-deposition of the organic layers (Japanese Patent Application Laid-Open No. H10-284248, page 2, lines 2-7).

However, many organic materials for forming a light-emitting layer are often compounds which are unstable with respect to heat, so there is a possibility that each of the methods described in Japanese Patent Application Laid-Open Nos. H05-182764 and H10-284248 results in a reduction in initial emission efficiency. Actually, the inventors of the present invention have observed a phenomenon of reducing the initial emission efficiency of a device when an organic material is formed into a film on a heated substrate for producing the device using generally known 4,4′-bis(N-carbazole)biphenyl (CBP) or tris[8-hydroxyquinolinato]aluminum (Alq₃) for a light-emitting layer.

The present invention has been made in order to solving the above problems, and an object of the present invention is to provide a method of producing an electronic device having improved durability without any reduction in initial performance such as initial emission efficiency.

### SUMMARY OF THE INVENTION

That is, according to one aspect of the present invention, there is provided a method of producing an electronic device including at least a first organic layer formation step of forming a first organic layer on a first electrode, and a second organic layer formation step of forming a second organic layer on the first organic layer, wherein the method further includes a heating step of heating the first electrode, and wherein the first organic layer formation step includes at least a first organic layer vapor-deposition step of forming the first organic layer on the heated first electrode by vapor-deposition and a cooling step of cooling the first organic layer.

According to the present invention, even when the heating step is introduced to improve a durable lifetime, the introduction of the cooling step results in the production of an excellent electronic device with its initial device performance such as initial emission efficiency being prevented from reducing.

### BRIEF DESCRIPTION OF THE DRAWING

FIGURE is a schematic view showing an example of the laminated structure of a light-emitting device of the present invention.

### DESCRIPTION OF THE PREFERRED EMBODIMENTS

Hereinafter, the present invention will be described in detail.

<Heating Step>

The heating step is a step of heating the first electrode formed on a substrate prior to the formation of the first organic layer.

A method of heating the first electrode is not particularly limited. Examples of the method include a method of heating the electrode by means of an infrared lamp heater and a method of bringing a hot plate into contact with the substrate or a support member for the substrate. The heating step is preferably performed in a vacuum environment. In addition, the heating step is preferably performed in a vacuum chamber different from that for the first organic layer vapor-deposition step because an organic material adhering to a chamber wall surface or the like may be heated to generate a decomposition product or the degree of vacuum may reduce during heating when the heating step and the first organic layer vapor-deposition step are performed in the same chamber.

<First Organic Layer Formation Step>

The first organic layer formation step is a step of forming the first organic layer on the first electrode, and includes the first organic layer vapor-deposition step and the cooling step.

[First Organic Layer Vapor-Deposition Step]

The first organic layer vapor-deposition step is a step of forming the first organic layer on the heated first electrode by vapor-deposition.

A general vacuum vapor-deposition method is used as a method of forming the first organic layer. The maximum temperature Ta of the first electrode in the first organic layer vapor-deposition step has only to be lower than the melting point or glass transition point of an organic material constituting the first organic layer, but is preferably 100° C. or higher. In addition, the temperature of the first electrode preferably reaches the maximum temperature Ta at the start time of vapor-deposition. When the maximum temperature Ta is made 100° C. or higher, water adsorbed to the substrate and the surface of the first electrode desorbs, so that adhesiveness between the first organic layer and the first electrode increases. As a result, for example, the hole-injection property of a hole transport layer of an organic light-emitting device is improved, so that the durability may be improved.

[Cooling Step]

The cooling step is a step of cooling the first organic layer.

The first organic layer may be cooled during the first organic layer vapor-deposition step, or may be cooled after the completion of the first organic layer vapor-deposition step. The cooling is preferably initiated after the completion of the first organic layer vapor-deposition step because the vapor-deposition of the first organic layer in a state where the first electrode is heated has a reducing effect on the mixing of water into the first organic layer and an increasing effect on the density of the layer.

The cooling step is performed in a vacuum environment, whereby the heating step, the first organic layer vapor-deposition step, the cooling step, and the second organic layer formation step can be continuously performed in a vacuum environment. A method of cooling the first organic layer in a vacuum is not particularly limited. A method of bringing the substrate or the support member for the substrate into contact with a cooling plate is preferably adopted. The first organic layer may be cooled by adjusting a production speed, and leaving the substrate to stand for a time period 10 or more times as long as a time period from the completion of the heating step to the start of the first organic layer vapor-deposition step.

The first organic layer may be cooled by leaving the substrate to stand in an inert gas in order to shorten a cooling time. In this case, it is preferable that the heating step and the first organic layer vapor-deposition step be continuously performed in a vacuum environment, the inert gas be then introduced into a vacuum chamber to cool the substrate, again a vacuum be established in the vacuum chamber and then the second organic layer formation step is performed.

The cooling step is preferably performed in a vacuum chamber different from that for the first organic layer vapor-deposition step for the same reason as that described with respect to the heating step.

<Second Organic Layer Formation Step>

The second organic layer formation step is a step of forming the second organic layer on the first organic layer.

A general vacuum vapor-deposition method is used as a method of forming the second organic layer. The maximum temperature Tb of the first organic layer in the second organic layer formation step has only to be equal to or lower than a temperature at which damage is not given to an organic material constituting the second organic layer, but is preferably lower than the maximum temperature Ta of the first electrode in the first organic layer vapor-deposition step by 50° C. or more. In addition, it is preferable that a temperature at the start time of the formation of the second organic layer becomes the maximum temperature Tb. When Tb is lower than Ta by 50° C. or more, the temperature of the first organic layer is reduced by 50° C. or more, so that there is obtained an effect of further bringing the first organic layer into close contact with the first electrode.

<Electronic Device>

An electronic device can be produced by forming an additional organic layer on the second organic layer as required, and forming the second electrode.

Examples of an electronic device produced according to the present invention include electronic devices each having an organic layer, such as an organic light-emitting device, an organic TFT, and an organic battery, for example, a solar battery. The method of the present invention is particularly useful as a method of producing an organic light-emitting device (organic EL device) having a plurality of organic layers sandwiched between a pair of electrodes as shown in FIGURE.

In FIGURE, reference numeral 1 denotes a substrate; 2, an anode (first electrode); 3, a hole transport layer (first organic layer); 4, a light-emitting layer (second organic layer); 5, an electron transport layer; 6, an electron injection layer; and 7, a cathode.

Of such organic light-emitting devices, an organic light-emitting device including a hole transport layer containing an organic compound having a structure represented by the following structural formula [1] is preferable. 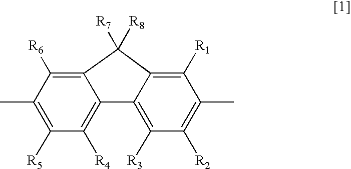
(R₁ to R₈ each represent a hydrogen atom, a halogen atom, a substituted or unsubstituted alkyl group, a substituted or unsubstituted aralkyl group, a substituted or unsubstituted cycloalkyl group, a substituted or unsubstituted alkenyl group, a substituted or unsubstituted cycloalkenyl group, a substituted or unsubstituted alkoxy group, a substituted or unsubstituted aryl group, a substituted or unsubstituted heterocyclic group, a substituted or unsubstituted amino group, a substituted or unsubstituted carbonyl group, a nitro group, a cyano group, a substituted or unsubstituted ester group, or a substituted or unsubstituted carbamoyl group.)

The above structure, which is referred to as a fluorene-type structure, is preferable because of its higher heat resistance than that of a typical biphenyl-type structure.

Hereinafter, examples of the present invention will be described. Organic compounds and device constitutions used in the examples are particularly preferable examples. However, the present invention is not limited thereto.

### EXAMPLE 1

Indium tin oxide (ITO) was formed into a film having a thickness of 120 nm on a transparent substrate 1 by sputtering, and the film was used as an anode (first electrode) 2. After that, the anode 2 was subjected to ultrasonic cleaning in acetone and isopropyl alcohol (IPA) sequentially and dried, and was then additionally subjected to UV/ozone cleaning.

[Heating Step]

The cleaned substrate was attached to a substrate heating-cooling vacuum chamber connected to a vacuum vapor-deposition chamber (both vacuum chambers were manufactured by ULVAC, Inc.), and evacuation was performed until a pressure of 1.33×10⁻⁴ Pa (1×10⁻⁶ Torr) was obtained. After that, the surface of the anode was heated by an infrared lamp heater placed in the substrate heating-cooling vacuum chamber until the temperature of the anode surface became 150° C., and then this temperature was held for 5 minutes. The temperature of the surface was measured by means of a thermocouple brought into contact with the anode.

[First Organic Layer Vapor-Deposition Step]

The substrate was conveyed in a vacuum by means of a mechanical arm to the vacuum vapor-deposition chamber provided with a material, and a hole transportable compound (having a glass transition point of 137° C.) represented by the following formula was formed into a hole transport layer 3 having a thickness of 50 nm on the anode 2. The film formation was initiated 3 minutes after the substrate had been conveyed to the vacuum vapor-deposition chamber. The temperature of the surface of the anode at this time was 110° C. 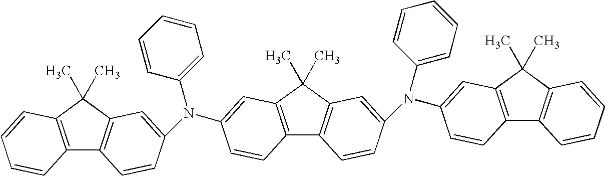
[Cooling Step]

The substrate was conveyed by means of a mechanical arm to the substrate heating-cooling vacuum chamber in a vacuum. Then, a support member for the substrate was brought into contact with a water cooling-type cooling plate placed in the substrate heating-cooling vacuum chamber, and the temperature of the surface of the hole transport layer was cooled to 50° C. over 7 minutes. After that, the substrate was conveyed by means of a mechanical arm to the vacuum vapor-deposition chamber in a vacuum.

[Second Organic Layer Formation Step]

A co-vapor-deposited film of coumarin 6 (1.0 wt %) represented by the following formula and tris[8-hydroxyquinolinato]aluminum (Alq₃) having a thickness of 30 nm was formed on the hole transport layer 3, to form a light-emitting layer 4. The temperature of the surface of the hole transport layer at the start tome of the film formation was 45° C. The temperature of the surface was measured by a thermocouple brought into contact with the hole transport layer.

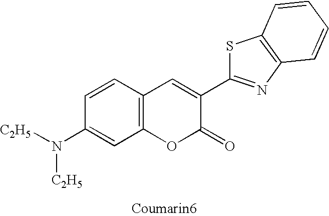

Next, a phenanthroline compound represented by the following formula was formed into an electron transport layer 5 having a thickness of 10 nm. Next, lithium fluoride was formed into a film having a thickness of 0.5 nm on the electron transport layer 5, and the film was used as an electron injection layer 6. Finally, aluminum having a thickness of 150 nm was vapor-deposited onto the electron injection layer 6 to serve as a cathode 7. After that, the substrate was transferred to a glove box coupled to the vacuum vapor-deposition chamber, and was sealed with a glass cap filled with a drying agent under a nitrogen atmosphere.

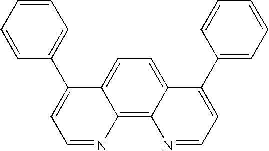

A DC voltage gradually increasing from 0 V in an increment of 0.25 V was applied to the produced organic light-emitting device to examine the luminescent characteristics of the device. As shown in Table 1, the device had an initial emission efficiency of 7.3 cd/A. Furthermore, durability measurement was performed at a constant current of 30 mA/cm². As a result, the deterioration ratio of the device after 24 hours was 12%.

### EXAMPLE 2

A light-emitting device was produced in the same manner as in Example 1 except that the cooling step was changed as follows, and was similarly evaluated. Table 1 shows the results.

[Cooling Step]

The temperature of the substrate was cooled to 50° C. over 30 minutes in the vacuum vapor-deposition chamber. The temperature of the surface of the hole transport layer at the start time of the formation of the light-emitting layer was 45° C.

### EXAMPLE 3

A light-emitting device was produced in the same manner as in Example 1 except that the cooling step was changed as follows, and was similarly evaluated. Table 1 shows the results.

[Cooling Step]

The substrate was conveyed by means of a mechanical arm to the substrate heating-cooling vacuum chamber in a vacuum. Then, a nitrogen gas was introduced into the substrate heating-cooling vacuum chamber, and the temperature of the surface of the hole transport layer was cooled to 50° C. over 5 minutes. After that, the substrate heating-cooling vacuum chamber was evacuated to 1.33×10⁻⁴ Pa (1×10⁻⁶ Torr). After that, the substrate was conveyed by means of a mechanical arm to the vacuum vapor-deposition chamber in a vacuum. The temperature of the surface of the hole transport layer at the start time of the formation of the light-emitting layer was 45° C.

### COMPARATIVE EXAMPLE 1

A light-emitting device was produced in the same manner as in Example 1 except that no cooling step was performed, and was similarly evaluated. The temperature of the surface of the hole transport layer at the start time of the formation of the light-emitting layer was 90° C. Table 1 shows the results.

As shown in Table 1, the device had a deterioration ratio comparable to that of each of Examples 1 to 3, but had a reduced initial emission efficiency as compared to those of Examples 1 to 3.

### COMPARATIVE EXAMPLE 2

A light-emitting device was produced in the same manner as in Example 1 except that neither the heating step nor the cooling step was performed, and was similarly evaluated. Each of the temperature of the surface of the anode at the start time of the formation of the hole transport layer and the temperature of the surface of the hole transport layer upon initiation of the formation of the light-emitting layer was 24° C. Table 1 shows the results.

As shown in Table 1, the device had an initial emission efficiency comparable to that of each of Examples 1 to 3, but had an increased deterioration ratio as compared to those of Examples 1 to 3.

### EXAMPLE 4

This example represents an application example to a light-emitting device using chromium (Cr) functioning as a reflection electrode for an anode and an indium tin oxide (ITO) functioning as a transparent emitted-light output electrode for a cathode, that is, a top emission-type device.

Chromium (Cr) was formed into a film having a thickness of 200 nm on a substrate 1 by sputtering, and the film was used as an anode (first electrode) 2. After that, the substrate was subjected to UV/ozone cleaning.

A hole transport layer 3, a light-emitting layer 4, and an electron transport layer 5 were formed on the anode 2 in the same manner as in Example 1. A co-vapor-deposited film of the phenanthroline compound used in Example 1 and cesium carbonate (3 vol %) as an electron injection dopant having a thickness of 40 nm was formed thereon, and the film was used as an electron injection layer 6. Subsequently, the substrate was transferred to another sputtering device (manufactured by Osaka Vacuum, Ltd.), and an indium tin oxide (ITO) was formed into a film having a thickness of 60 nm on the electron injection layer 6 by sputtering to obtain a transparent emitted light output cathode 7. After that, the substrate was transferred to a glove box, and was sealed with a glass cap filled with a drying agent in a nitrogen atmosphere.

The produced organic light-emitting device was evaluated in the same manner as in Example 1. Table 1 shows the results.

### COMPARATIVE EXAMPLE 3

A light-emitting device was produced in the same manner as in Example 4 except that no cooling step was performed, and was similarly evaluated. The temperature of the surface of the hole transport layer at the start time of the formation of the light-emitting layer was 90° C. Table 1 shows the results.

As shown in Table 1, the device had a deterioration ratio comparable to that of Example 4, but had a reduced initial emission efficiency as compared to that of Example 4.

TABLE 1

| | | | Initial | |
|---|---|---|---|---|
| | | | emission | Deterioration |
| | Heating | Cooling | efficiency | ratio |
| | step | step | (Cd/A) | (%) |
| Example 1 | Present | Cooling | 7.3 | 12 |
| | | plate | | |
| Example 2 | Present | Waiting | 7.0 | 14 |
| | | for 30 | | |
| | | minutes | | |
| Example 3 | Present | Introduction | 6.8 | 15 |
| | | of | | |
| | | N₂ gas | | |
| Comparative | Present | Absent | 5.6 | 12 |
| Example 1 | | | | |
| Comparative | Absent | Absent | 7.6 | 31 |
| Example 2 | | | | |
| Example 4 | Present | Cooling | 6.8 | 22 |
| | | plate | | |
| Comparative | Present | Absent | 5.2 | 21 |
| Example 3 | | | | |

As can be seen from Table 1, according to the production method of the present invention, even when the heating step is introduced to improve a durable lifetime, the introduction of the cooling step can prevent a reduction in initial emission efficiency.

This application claims priority from Japanese Patent Application No. 2005-035382 filed on Feb. 14, 2005, which is hereby incorporated by reference herein.

What is claimed is:

1. A method of producing an electronic device comprising:
a first organic layer formation step of forming a first organic layer on a first electrode; and
a second organic layer formation step of forming a second organic layer on the first organic layer,
wherein the method further comprised a heating step of heating the first electrode before the first organic layer formation step, and
wherein the first organic layer formation step comprises a first organic layer vapor-deposition step of forming the first organic layer on the heated first electrode by vapor-deposition and a cooling step of cooling the first organic layer.

2. A method of producing an electronic device according to claim 1, wherein the cooling step is a step after the first organic layer vapor-deposition step.

3. A method of producing an electronic device according to claim 1, wherein a maximum temperature Ta of the first electrode in the first organic layer vapor-deposition step is 100° C. or higher.

4. A method of producing an electronic device according to claim 1, wherein a maximum temperature Tb of the first organic layer in the second organic layer formation step is lower than the maximum temperature Ta of the first electrode in the first organic layer vapor-deposition step by 50° C. or more.

5. A method of producing an electronic device according to claim 1, wherein the cooling step is performed in a vacuum environment.

6. A method of producing an electronic device according to claim 5, wherein the cooling step is a step of bringing a substrate on which the first electrode is formed or a support member for the substrate into contact with a cooling plate.

7. A method of producing an electronic device according to claim 5, wherein the cooling step is a step of leaving the substrate on which the first electrode is formed to stand for a time period 10 or more times as long as a time period from completion of the heating step to start of the first organic layer vapor-deposition step.

8. A method of producing an electronic device according to claim 1, wherein the heating step, the first organic layer vapor-deposition step, the cooling step, and the second organic layer formation step are continuously performed in a vacuum environment.

9. A method of producing an electronic device according to claim 1, wherein the cooling step is a step of leaving the substrate on which the first electrode is formed to stand in an inert gas.

10. A method of producing an electronic device according to claim 9, wherein the heating step and the first organic layer vapor-deposition step are continuously performed in a vacuum environment, the inert gas is introduced into the cooling step, and a vacuum environment is established again in the second organic layer formation step.

11. A method of producing an electronic device according to claim 1, wherein the first organic layer is a hole transport layer, the second organic layer is a light-emitting layer, and the electronic device is an organic light-emitting device.

12. A method of producing an electronic device according to claim 11, wherein the hole transport layer contains an organic compound having a structure represented by the following structural formula [1]: 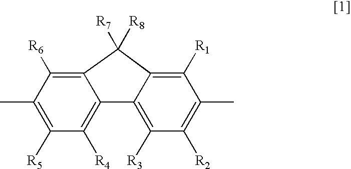
wherein R₁ to R₈ each represent a hydrogen atom, a halogen atom, a substituted or unsubstituted alkyl group, a substituted or unsubstituted aralkyl group, a substituted or unsubstituted cycloalkyl group, a substituted or unsubstituted alkenyl group, a substituted or unsubstituted cycloalkenyl group, a substituted or unsubstituted alkoxy group, a substituted or unsubstituted aryl group, a substituted or unsubstituted heterocyclic group, a substituted or unsubstituted amino group, a substituted or unsubstituted carbonyl group, a nitro group, a cyano group, a substituted or unsubstituted ester group, or a substituted or unsubstituted carbamoyl group.
